(19) United States
(12) Patent Application Publication
(10) Pub. No.: US 2025/0364261 A1
(43) Pub. Date: Nov. 27, 2025

(54) PLASMA ETCH SYSTEM INCLUDING TUNABLE PLASMA SHEATH

(71) Applicant: Taiwan Semiconductor Manufacturing Company, Ltd., Hsinchu (TW)

(72) Inventors: Ming-Hsun LIN, Hsinchu City (TW); Ting-Jung CHEN, Hsinchu County (TW); Yu JIANG, Hsinchu (TW)

(21) Appl. No.: 19/293,316

(22) Filed: Aug. 7, 2025

Related U.S. Application Data
(62) Division of application No. 18/164,117, filed on Feb. 3, 2023.

(51) Int. Cl. H01L 21/3065; H01J 37/32; H01L 21/683

(52) U.S. Cl. CPC H01L 21/3065; H01J 37/32642; H01J 37/32715; H01L 21/6833; H01J 2237/334

(57) ABSTRACT

Some implementations described herein include an etch tool including a combination bottom shadow ring component including a moveable inner ring component and a fixed inner ring component. The moveable inner ring component provides for an adjustability of an effective thickness of the combination bottom shadow ring component during an etching operation. The adjustability (e.g., “tunability”) of the effective thickness of the combination bottom shadow ring component enables flexibility and is conducive to changes in one or more parameters related to different etch recipes for a semiconductor substrate. Additionally, the fixed inner ring component shadows beveled regions of the semiconductor substrate during the etching operation to reduce a likelihood of damage to the beveled regions.

### RELATED APPLICATION

This application is a divisional of U.S. patent application Ser. No. 18/164,117, filed Feb. 3, 2023, which is incorporated herein by reference in its entirety.

### BACKGROUND

An etch tool is a semiconductor processing tool that is capable of etching various types of materials of a semiconductor substrate. In some implementations, the etch tool may correspond to a plasma etch tool that uses a plasma-assisted etch technique (e.g., a plasma sputtering technique or another type of technique) that involves use of an ionized gas to isotropically or directionally etch the semiconductor substrate.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1C are diagrams of an example implementation of a plasma etch system described herein.

FIGS. 2A-2C are diagrams related to an example implementation of a plasma sheath described herein.

FIG. 3 is a diagram of an example implementation including details of combination ring components used to tune the plasma sheath described herein.

FIG. 4 is a diagram of an example implementation of a mechanical lift component described herein.

FIGS. 5A-5E are diagrams of an example series of operations performed by the plasma etch system described herein.

FIG. 6 is one or more devices of FIGS. 1A-1C described herein.

FIG. 7 is a flowchart of an example process associated with tuning a plasma sheath for edge etch profile control as described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

During an etching operation using a plasma, electrons may be depleted from a boundary interface between an electrode of the etch tool and the plasma to create a region that contains positive ions and neutrals. This region may be referred to as a plasma sheath. A discontinuity in an electromagnetic profile of the plasma sheath (e.g., “bending”) may tilt or deflect a directional etch which may cause an etch defect in a perimeter region of the semiconductor substrate. In some implementations, the etch defect may cause a formation of particulates and/or contamination to the semiconductor substrate during a subsequent dicing operation. To reduce a likelihood of the etch defect, the etch tool may include a bottom shadow ring component and/or an edge ring component to change the electromagnetic profile of the plasma sheath.

Some implementations described herein include plasma etch tool including a combination bottom shadow ring component including a moveable inner ring component and a fixed inner ring component. In some cases, an effectiveness of the combination bottom shadow ring component to contribute to the reduction in the likelihood of the etch defect may depend on a height of a top surface of the combination bottom shadow ring component. The moveable inner ring component provides for an adjustability of the height of the top surface of the moveable inner ring component during an etching operation. The adjustability (e.g., “tunability”) of the moveable inner ring component enables flexibility enables tailoring of one or more parameters related to different etch recipes for a semiconductor substrate. Additionally, the fixed inner ring component includes a shadow region that protects beveled regions at a perimeter of the semiconductor substrate during the etching operation when the moveable inner ring component is raised, which reduces a likelihood of damage to the beveled regions.

In this way, a productivity of the etch tool including the combination bottom shadow ring component may be increased relative to another etch tool not including the combination bottom shadow ring component (e.g., a downtime of the etch tool for changing between bottom shadow ring components having different thicknesses based on an etch recipe may be eliminated, among other examples). Additionally, a yield of a semiconductor product fabricated using the etch tool may increase (relative to the other tool) due to a reduction in particulates and/or contamination during a subsequent dicing operation, effective to reduce an amount of resources required to fabricate a volume of the semiconductor product (e.g., an install base of the etch tool, an amount of semiconductor substrates, manpower, and/or supporting computing resources, among other examples).

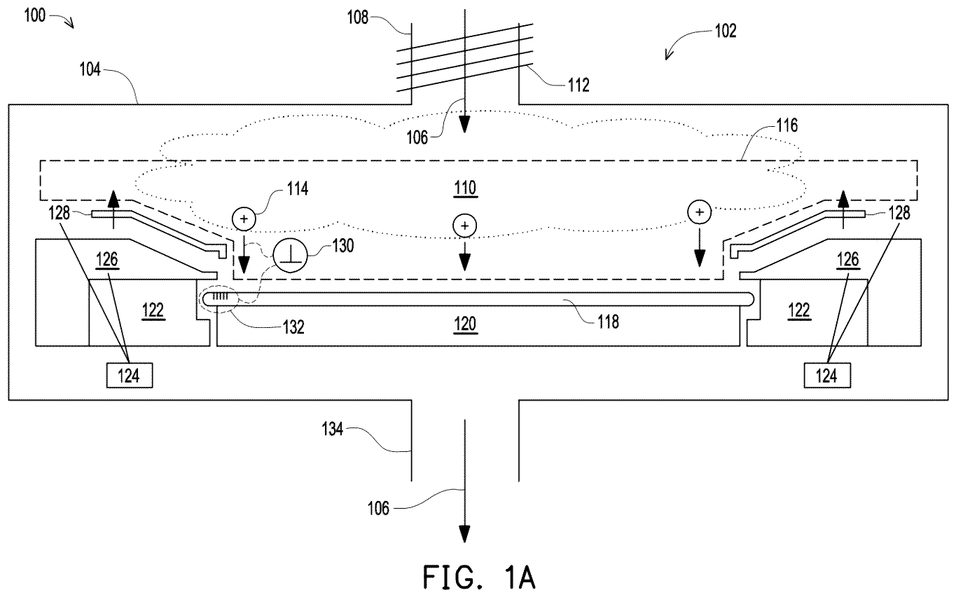

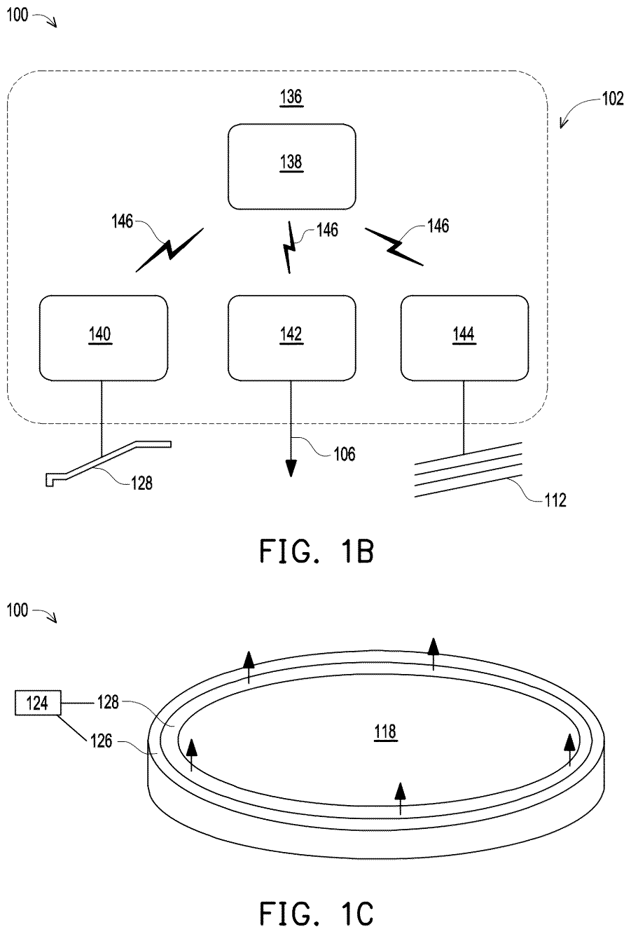

FIGS. 1A-1C are diagrams of an example implementation 100 of a plasma etch system 102 described herein. In some implementations, the one or more components of the plasma etch system 102 are included in a plasma etch tool. As shown in the side view of FIG. 1A, the plasma etch system 102 may include a chamber 104 to receive a gas 106 through an inlet 108.

The gas 106 may be a source gas that includes small molecules rich in chlorine or fluorine. For example, carbon tetra fluorine may be utilized as the gas 106 to etch silicon, chlorine may be utilized as the gas 106 to etch aluminum, trifluoro methane may be used as the gas 106 to etch silicon dioxide and silicon nitride, and/or the like. The gas 106 may also include oxygen that is used to oxidize a photoresist and facilitate removal of the photoresist.

In some implementations, the gas 106 is converted to a plasma 110 based on applying a high frequency electric field (e.g., provided by a power supply) to an electrode 112. The high frequency electric field may be negatively biased, which results in a region including an excess of ions 114 (e.g., positively charged ions) in the plasma 110. This region is referred to as a plasma sheath 116, which may also be referred to as an electrostatic sheath or a Debye sheath.

The plasma 110 may be above a semiconductor substrate 118 (e.g., a silicon wafer, among other examples). In some implementations, the semiconductor substrate 118 includes a round shape. In some implementations the semiconductor substrate 118 includes another shape, such as a square shape or a rectangular shape, among other example. In some implementations, the semiconductor substrate 118 includes at least one integrated circuit (IC) die that is partially or wholly formed. In some implementations, the chamber 104 may be sized and or shaped based on the size and/or shape of the semiconductor substrate 118.

Using the gas 106 and/or the plasma 110, the plasma etch system 102 may remove material (e.g., etch the material) from the semiconductor substrate 118. In some implementations, a portion of semiconductor substrate 118 is protected from an etchant (e.g., the gas 106 and/or the plasma 110) by a masking material that resists etching. For example, the masking material may include a photoresist that is patterned using photolithography.

As shown in FIG. 1A, the semiconductor substrate 118 is supported by an electrostatic chuck 120. In some implementations, a power supply may provide a bias voltage to the electrostatic chuck 120 to generate an attractive force that causes the semiconductor substrate 118 to be retained on and supported by the electrostatic chuck 120 during processing of the semiconductor substrate 118.

The electrostatic chuck 120 may be sized and shaped depending on the size and a shape of the semiconductor substrate 118. In some implementations, the electrostatic chuck 120 is constructed of a material or materials that are resistant to abrasion and/or corrosion caused by materials used to generate the plasma 110, and that can generate the attractive force between electrostatic chuck 120 and the semiconductor substrate 118. For example, the electrostatic chuck 120 may be constructed of a metal, such as aluminum or stainless steel, among other examples.

As further shown in FIG. 1A, the plasma etch system 102 includes an edge ring component 122. The edge ring component 122 may include a component that surrounds the semiconductor substrate 118 supported by the electrostatic chuck 120. The edge ring component 122 may improve electrical and fluid uniformity for the plasma 110 while the semiconductor substrate 118 is being processed by the plasma etch system 102. For example, a high bias voltage may be applied to edge ring component 122 (e.g., from a power supply) so that the edge ring component 122 may provide the electrical and fluid uniformity for the plasma 110.

The edge ring component 122 may be sized and shaped depending on a size and a shape of semiconductor substrate 118. For example, the edge ring component 122 may be circular shaped and may include an opening to enable the edge ring component 122 to surround semiconductor substrate 118 and electrostatic chuck 120. In some implementations, the edge ring component 122 is constructed of a material or materials that are resistant to abrasion and/or corrosion caused by materials used to generate the plasma, and that can provide the electrical and plasma uniformity for semiconductor substrate 118. For example, edge ring component 122 may be constructed of a metal, such as aluminum or stainless steel, among other examples.

The plasma etch system 102 further includes a combination bottom shadow ring component 124. The combination bottom shadow ring component 124 includes a fixed outer ring component 126 and a moveable inner ring component 128 that is above the fixed outer ring component 126 and the edge ring component 122. In some implementations, the fixed outer ring component 126 and/or the moveable inner ring component 128 are constructed of a material or materials that are resistant to abrasion and/or corrosion caused by materials used to generate the plasma, and that can provide electrical isolation. For example, the fixed outer ring component 126 and/or the moveable inner ring component 128 may be constructed of a dielectric, such as silicon dioxide, aluminum dioxide, silicon carbide, or yttrium oxide, among other examples. In some implementations, the fixed outer ring component 126 and the edge ring component 122 are combined as a single component.

As described in greater detail in connection with FIGS. 1B-7 and elsewhere herein, a height of the moveable inner ring component 128 may be adjusted based on an etch recipe (e.g., parameters related to a type of the gas 106, a pressure within the chamber 104, and/or an amount of a material to be removed from the semiconductor substrate 118, among other examples). By adjusting the height of the moveable inner ring component 128, a profile of an electromagnetic field (e.g., a distribution or shape of electric potential bands, among other examples) within the plasma sheath 116 may be adjusted to redirect and improve a verticality 130 of a bombardment of the ions 114 upon the surface of the semiconductor substrate 118.

In some implementations, adjusting the electromagnetic field of the plasma sheath 116 results in an etch profile 132 that is vertical at or near an edge region (e.g., a beveled region) of the semiconductor substrate 118. The etch profile 132 that is vertical may reduce a likelihood of particulates being generated during a subsequent dicing operation to reduce a likelihood of contamination and/or other defects to IC dies included on the semiconductor substrate 118. Additionally, or alternatively, a shadow region of the fixed outer ring component 126 may protect the edge region of the semiconductor substrate 118 during an etching operation to further reduce a likelihood of damage to the semiconductor substrate 118 (e.g., etch defects, among other examples).

In this way, a productivity of an etch tool including the combination bottom shadow ring component 124 may be increased relative to another etch tool not including the combination bottom shadow ring component 124. For example, a downtime of the etch tool for changing between different shadow rings for different etch recipes may be reduced and/or eliminated. Additionally, a yield of a semiconductor product fabricated using the etch tool may increase (relative to the other etch tool) to reduce an amount of resources required to fabricate a volume of the semiconductor product (e.g., an install base of the etch tool, a quantity of the semiconductor substrate 118, and or supporting computing resources, among other examples).

As shown in FIG. 1A, the chamber 104 may further include an outlet 134. The outlet 134 may exhaust the gas 106 and/or the plasma 110 to an environment external to the chamber 104.

The side view of FIG. 1B shows an example control system 136 that may be included as part of the plasma etch system 102. The control system 136 may include a controller 138, a mechanical lift component 140, a gas supply system 142, and a power supply 144. The controller 138 (e.g., a processor, a combination of a processor and memory, among other examples) may communicate with the mechanical lift component 140, the gas supply system 142, an/or the power supply 144 using one or more communication links 146. The one or more communication links 146 may include or more wireless-communication links, one or more wired-communication links, or a combination of one or more wireless-communication links and one or more wired-communication links, among other examples.

The mechanical lift component 140 may include a motor (e.g., a servo motor, a stepper motor, or a linear induction motor, among other examples). Additionally, or alternatively, the mechanical lift component 140 may include an actuator or a pneumatic cylinder. The mechanical lift component 140 may further include mechanical linkages that connect the mechanical lift component 140 to the moveable inner ring component 128. The mechanical lift component 140 may extend a height of the moveable inner ring component 128.

The gas supply system 142 may include a chamber, a pressurized vessel, and/or a network of conduits (e.g., piping or tubing, among other examples) to provide the gas 106 to a chamber (e.g., the chamber 104). Additionally, or alternatively, the gas supply system 142 may include a controllable valve to adjust a flow rate of the gas 106, adjust a pressure of the gas 106, or adjust a mixture of the gas 106, among other examples.

The power supply 144 may correspond to an alternating current (AC) power supply or a direct current (DC) power supply. The power supply 144 is connected to the electrode 112, which may be included as part of one or components of the plasma etch system 102 (e.g., included as part of the inlet 108, the electrostatic chuck 120, and/or the edge ring component 122, among other examples). In some implementations, the power supply 144 provides a high frequency electrical field to the electrode 112 to excite the gas 106 into a plasma (e.g., the plasma 110).

The controller 138 may adjust a setting of the mechanical lift component 140, the gas supply system 142, and/or the power supply 144 using a machine learning model. The machine learning model may include and/or may be associated with one or more of a neural network, a random forest model, a clustering model, or a regression model, among other examples. For example, in some implementations the controller 138 uses the machine learning model to adjust a setting of the mechanical lift component 140 to control a height of the moveable inner ring component 128 by providing parameters related to one or more etch recipes as input to the machine learning model, and using the machine learning model to determine a likelihood, probability, or confidence that a particular outcome (e.g., an adjustment to an electromagnetic field of the plasma sheath 116, a verticality 130 of a bombardment of the ions 114, and/or a change to the etch profile 132, among other examples) will be achieved using the candidate parameters. In some implementations, the controller 138 provides a desired etch profile of an edge region of a semiconductor substrate (e.g., the etch profile 132 of the edge region of the semiconductor substrate 118) as input to the machine learning model, and the controller 138 uses the machine learning model to determine or identify a particular combination of adjustments to settings of the mechanical lift component 140, the gas supply system 142, and/or the power supply 144 that are likely to achieve the desired etch profile.

The controller 138 (or another system) may train, update, and/or refine the machine learning model to increase the accuracy of the outcomes and/or parameters determined using the machine learning model. The controller 138 may train, update, and/or refine the machine learning model based on feedback and/or results from the subsequent etching operation, as well as from historical or related etching operations (e.g., from hundreds, thousands, or more historical or related etching operations performed by the plasma etch system 102.

FIG. 1C shows an isometric view of the combination bottom shadow ring component 124 relative to the semiconductor substrate 118. As shown in FIG. 1C, the combination bottom shadow ring component 124 includes the fixed outer ring component 126 and the moveable inner ring component 128. As shown, a position of the moveable inner ring component 128 may be adjusted relative to the semiconductor substrate 118 and/or the fixed outer ring component 126 to change a height of the moveable inner ring component 128.

FIGS. 1A-1C describe the plasma etch system 102 (e.g., a portion of a plasma etch tool). The plasma etch system 102 includes the chamber 104. The plasma etch system 102 includes the electrostatic chuck 120 in the chamber 104 to support the semiconductor substrate 118. The plasma etch system 102 includes a subsystem configured to adjust an electromagnetic profile of the plasma sheath 116 within the chamber 104 above a perimeter region of the semiconductor substrate 118. The subsystem includes the combination bottom shadow ring component 124. The combination bottom shadow ring component 124 includes the fixed outer ring component 126 and the moveable inner ring component 128 above the fixed outer ring component 126. As part of the subsystem, the mechanical lift component 140 is connected to the moveable inner ring component 128. In some implementations, the mechanical lift component 140 is configured to adjust a height of the moveable inner ring component 128 to adjust the electromagnetic profile of the plasma sheath 116.

Additionally, or alternatively, the plasma etch system 102 may perform a series of operations. The series of operations includes receiving the semiconductor substrate 118. The series of operations includes generating the plasma 110 that includes the plasma sheath 116 above the semiconductor substrate 118. The series of operations includes adjusting a height of the moveable inner ring component 128 of multiple ring components to adjust an electromagnetic profile of the plasma sheath 116. In some implementations, the multiple ring components includes the edge ring component 122, the fixed outer ring component 126, and the moveable inner ring component 128, where the moveable inner ring component 128 is above the edge ring component 122 and the fixed outer ring component 126.

The number and arrangement of devices shown in FIGS. 1A-1C are provided as one or more examples. In practice, there may be additional devices, fewer devices, different devices, or differently arranged devices than those shown in FIGS. 1A-1C. Furthermore, two or more devices shown in FIGS. 1A-1C may be implemented within a single device, or a single device shown in FIGS. 1A-1C may be implemented as multiple, distributed devices. Additionally, or alternatively, a set of devices (e.g., one or more devices) of the example implementation 100 may perform one or more functions described as being performed by another set of devices of the example implementation 100.

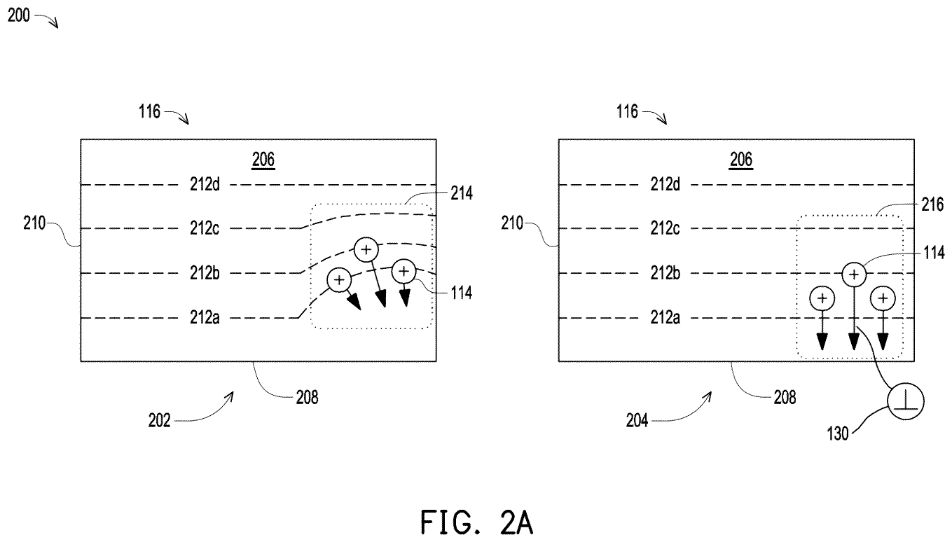

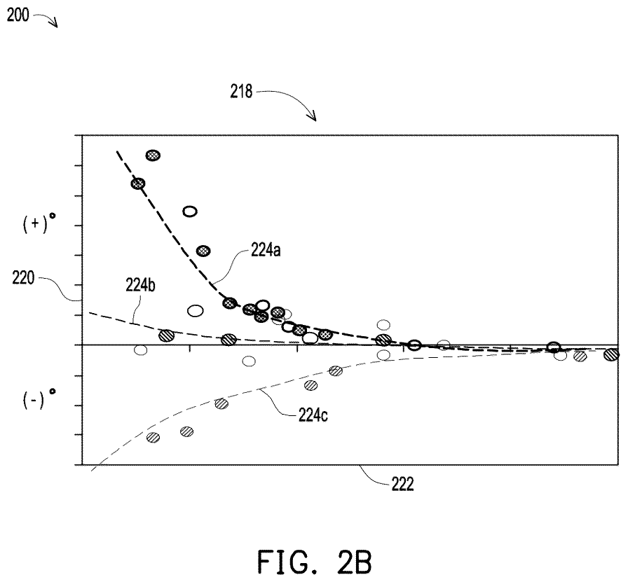

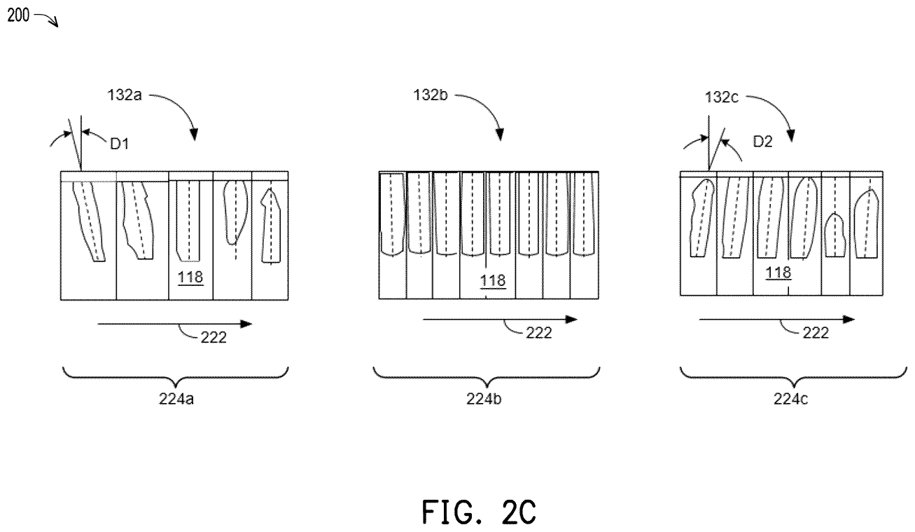

FIGS. 2A-2C are diagrams related to an example implementation 200 of the plasma sheath 116 described herein. The plasma sheath 116 may be formed as part of the plasma 110 formed by the plasma etch system 102 of FIGS. 1A-1C.

As shown in examples 202 and 204 of the side view of FIG. 2A, the plasma sheath 116 includes an electromagnetic field 206 distributed above a horizontal axis 208 and along a vertical axis 210 The horizontal axis 208 may be parallel to a surface of a semiconductor substrate (e.g., the semiconductor substrate 118) and the vertical axis may be parallel to vertical edges of one or more ring components (e.g., vertical edges of the edge ring component 122, the fixed outer ring component 126, and/or the moveable inner ring component 128, among other examples).

The electromagnetic field 206 includes a plurality of electrical potential bands 212a-212d corresponding to different electrical potentials. For example, the electrical potential band 212a may correspond to approximately 500 volts (V), the electrical potential band 212b may correspond to approximately 400 V, the electrical potential band 212c may correspond to approximately 300 V, and the electrical potential band 212d may correspond to approximately 200. However, other values and ranges for voltages of the electrical potential bands 212a-212d are within the scope of the present disclosure.

In some implementations, and based on properties that include a thickness of the plasma sheath 116, dimensions related to one or more of the ring components (e.g., an affective thickness of the combination bottom shadow ring component 124 based on a height of the moveable inner ring component 128, among other examples), materials of one or more of the ring components, and parameters included in an etch recipe, a profile of the electromagnetic field 206 (e.g., a distribution and/or shape of the electrical potential bands 212a-212d) may vary.

As shown in example 202, the profile of the electromagnetic field 206 includes a concavity 214 (e.g., the electrical potential bands 212a-212 are curved or bent). In some implementations, the concavity 214 is referred to as “sheath bending”. As shown in example 202, the concavity 214 may cause a redirection of the ions 114 during an etching operation. Such a redirection may cause etching defects in the semiconductor substrate (e.g., the etch profile 132 near the perimeter region of the semiconductor substrate 118 may be angled and increase a likelihood of generating particulates or contamination during a dicing of the semiconductor substrate 118, among other examples).

As shown in example 204, the profile of the electromagnetic field 206 includes a region including a uniformity 216 (e.g., the electrical potential bands 212a-212c are evenly distributed and approximately linear) As shown in example 204, the uniformity 216 may improve the verticality 130 of the ions 114 during an etching operation. Such an improvement may correspond to a reduction in etching defects in the semiconductor substrate (e.g., the etch profile 132 near the perimeter region of the semiconductor substrate 118 may be orthogonal and reduce a likelihood of generating particulates or contamination during a dicing of the semiconductor substrate 118, among other examples)

Turning to FIG. 2B, example 218 shows a relationship related to an effective thickness of a combination bottom shadow ring component (e.g., a combined thickness of the combination bottom shadow ring component 124, including the fixed outer ring component 126 and the moveable inner ring component 128 over fixed outer ring component 126). Such a relationship may be used to determine a setting of a height of the moveable inner ring component 128 to achieve a target profile of an electromagnetic field (e.g., a distribution of the electrical potential bands 212a-212d of the electromagnetic field 206, among other examples).

As shown in the example 218, a tilt angle 220 (e.g., in degrees) may vary depending on a location 222 (e.g., in millimeters) relative to an edge of a semiconductor substrate (e.g., the semiconductor substrate 118). The tilt angle 220, which may correspond to an angle of bombardment of ions (e.g., the ions 114 included in the plasma sheath 116) may be measured relative to a verticality (e.g., the verticality 130 relative to the semiconductor substrate 118, among other examples).

In the example 218, the relationship for a first effective thickness 224a (e.g., a nominal thickness), a second effective thickness 224b, and a third effective thickness 224c are illustrated. The effective thicknesses 224a-224c may correspond to respective heights of a ring component (e.g., the moveable inner ring component 128). In some implementations, the second effective thickness 224b corresponds to a thickness factor that is approximately 1.8×the first effective thickness 224a. In some implementations, the third effective thickness 224c corresponds to a thickness factor that is approximately 2.3×the first effective thickness 224a. However, other thickness factors are within the scope of the present disclosure.

As in the example 218, the second effective thickness 224b (e.g., 1.8×the first effective thickness 224) may reduce the tilt angle 220 at or near an edge of the semiconductor substrate and increase a verticality (e.g., the verticality 130) relative to the first effective thickness 224a and/or the third effective thickness 224c. By increasing the verticality, a likelihood of etching defects near the edge of the semiconductor substrate may be reduced.

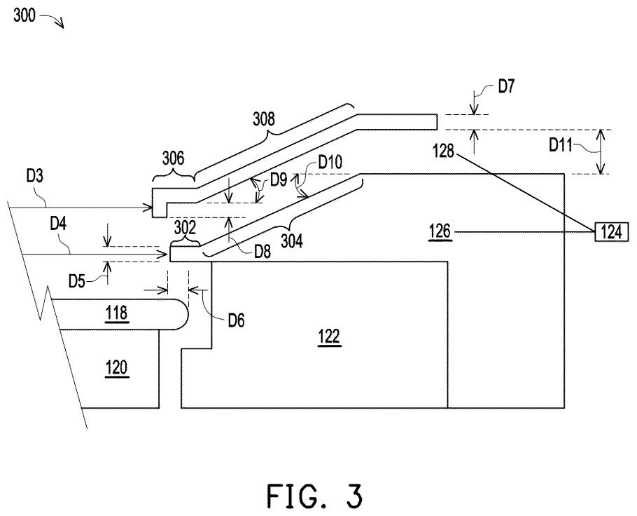

FIG. 2C shows a side view of example etch profiles 132a-132c in the semiconductor substrate 118 that corresponding to the effective thicknesses 224a-224c of FIG. 2B. As shown in the FIG. 2C, the etch profile 132a includes multiple portions that are titled at a tilt angle D1. Further, and as shown in FIG. 3C, the etch profile 132b includes multiple portions that are approximately vertical (e.g., orthogonal to the semiconductor substrate 118). Further, and as shown in FIG. 3C, the etch profile 132c includes multiple portions that are tilted at a tilt angle D2. Relative to the etch profile 132a and/or the etch profile 132c, the etch profile 132b may reduce a likelihood of a particulates or contamination being generated during a subsequent dicing operation to the semiconductor substrate 118.

As an example, and in in some implementations, the tilt angle D1 corresponds to a positive tilt angle included in a range of approximately +7 degrees to approximately +13 degrees. Additionally, or alternatively, the tilt angle D2 may correspond to a negative tilt angle included in a range of approximately −7 degrees to approximately −13 degrees. However, other values and ranges for the tilt angles D1 and D2 are within the scope of the present disclosure.

As indicated above, FIGS. 2A-2C are provided as an example. Other examples may differ from what is described with regard to FIGS. 2A-2C.

FIG. 3 is a diagram of example an example implementation 300 including details of the combination ring components 124 (e.g., the fixed outer ring component 126 and the moveable inner ring component 128) used to tune the plasma sheath 116 described herein. The implementation 300 includes the semiconductor substrate 118 on the electrostatic chuck 120, where the electrostatic chuck 120 is side-by-side with the edge ring component 122 (e.g., the edge ring component 122 is side-by-side with the electrostatic chuck 120). As shown in the side view of FIG. 3, an inner width D3 (e.g., an inner diameter of a circular shape, among other examples) of the moveable inner ring component 128 may be lesser relative to an inner width D4 of the fixed outer ring component 126. For example, and in a case where a width of the semiconductor substrate is approximately 300 millimeters, the inner width D3 may be included in a range of approximately 295 millimeters to approximately 296 millimeters and the inner width D4 may be included in a range of approximately 296 millimeters to approximately 298 millimeters. However, other values and ranges for the inner width D3 and the inner width D4 are within the scope of the present disclosure.

The fixed outer edge component includes a shadow portion 302 and an angled portion 304 that includes an angled surface. In some implementations, and as shown in FIG. 3, the shadow portion extends over the semiconductor substrate 118 that is secured by the electrostatic chuck 120. The shadow portion 302 may have a thickness D5 that is included in a range of approximately 0.54 millimeters to approximately 0.66 millimeters. However, other values and ranges for the thickness D5 are within the scope of the present disclosure.

Additionally, or alternatively, the shadow portion 302 may include an overhang length D6 that is included in a range of approximately 1 millimeter to approximately 2 millimeters. If the overhang length D1 is less than approximately 1 millimeter, the shadow portion 302 may not protect an edge region (e.g., a beveled region) of the semiconductor substrate 118 during when the moveable inner ring component 128 is raised. If the overhang length D6 is greater than approximately 2 millimeters, the shadow portion 302 may prevent etching of an inner region (e.g., an IC die) of the semiconductor substrate 118. However, other values and ranges for overhang length D6 of the shadow portion are within the scope of the present disclosure.

As shown in FIG. 3, the moveable inner ring component 128 may include a thickness D7 that approximates the thickness D5 of the shadow portion 302 (e.g., D7 may be included in the range of approximately 0.54 millimeters to approximately 0.66 millimeters). The moveable inner ring component 128 may further include a lip portion 306 and an angled portion 308 that includes an angled surface. The lip portion 306 may be configured to overlap an edge of the shadow portion 302, and include an overlap length D8 that approximates the thickness D5 of the shadow portion 302 (e.g., D8 may be included in a range of approximately 0.54 millimeters to approximately 0.66 millimeters). However, other values and ranges for the thickness D7 and the overlap length D8 are within the scope of the present disclosure.

As shown in FIG. 3, the angled portion 308 of the moveable inner ring component 128 is over the angled portion 304 of the fixed outer ring component 126. Further, the angled portion 308 may be oriented at an angle D9 that is complementary to an angle D10 at which the angled portion 304 is oriented. The angles D9 and D10 may allow surfaces (e.g., a complementary angled surface of the moveable inner ring component 128 and a complementary angled surface of the fixed outer ring component 126) to mate when the moveable inner ring component 128 is in a lowered position.

The angles D9 and D10 may be less than approximately 90 degrees. For example, and in some implementations, the angles D9 and D10 may each be included in a range of approximately 10 degrees to approximately 70 degrees. However, other values and ranges for the angles D9 and D10 are within the scope of the present disclosure.

A height D11 of a bottom surface of the moveable inner ring component 128 (e.g., and a height of a top surface of the moveable inner ring component 128) may be adjusted (e.g., raised by the mechanical lift component 140, among other examples). As described in connection with FIGS. 1A, 2A-2C, 4-7, and elsewhere herein, adjusting the height D11 may change an electromagnetic profile of a sheath (the electromagnetic profile 212a-212d of the plasma sheath 116, among other examples). In some implementations, the height D11 is included in range of approximately 1 millimeter to approximately 23 millimeters. If the height D11 is less than approximately 1 millimeter, a change to the electromagnetic profile of the sheath may be negligible (and ineffective to change a verticality of an etching operation near the perimeter of the semiconductor substrate 118). If the height D11 is greater than approximately 23 millimeters, a mechanical interference between the moveable inner ring component 128 and another structure of a plasma etch system (e.g., the chamber 104 of the plasma etch system 102, among other examples) may occur. However, other values and ranges for the height D11 are within the scope of the present disclosure.

As indicated above, FIG. 3 is provided as an example. Other examples, including dimensional properties of the ring components, may differ from what is described with regard to FIG. 3.

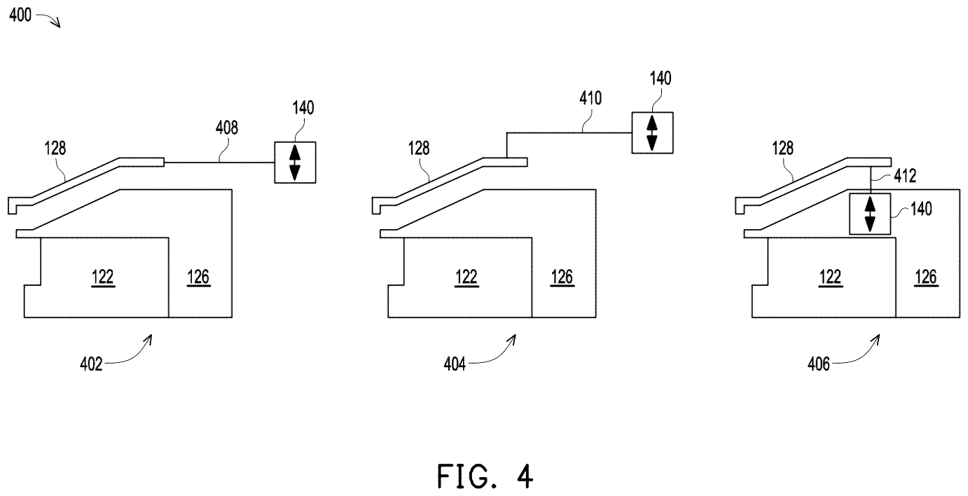

FIG. 4 is a diagram of an example implementation 400 of the mechanical lift component 140 described herein. FIG. 4 shows side views of examples 402-406, including details of the mechanical linkages connecting the mechanical lift component 140 and the moveable inner ring component 128.

The example 402 includes a mechanical linkage corresponding to an elevator component 408. The elevator component 408 may be side-by-side with the moveable inner ring component 128.

The example 404 includes a mechanical linkage corresponding to an upper cantilever component 410. The upper cantilever component 410 may be above the moveable inner ring component 128.

The example 406 includes a mechanical linkage corresponding to a pin component 412. The pin component 412 may be below the moveable inner ring component 128.

Each of the mechanical linkages (e.g., the elevator component 408, the upper cantilever component, and/or the pin component 412) may include a combination of beam components, fasteners, and/or guides (e.g., bearings, bushings, and/or slides, among other examples). Further, each of the mechanical linkages may include a material or materials that are resistant to abrasion and/or corrosion caused by materials used to generate a plasma (e.g., the plasma 110). For example, the mechanical linkages may include a metal, such as aluminum or stainless steel, among other examples. Additionally, or alternatively, each of the mechanical linkages may include a material that is resistant to wear and abrasion, such as an ultra-high molecular weight (UHM) material, among other examples.

As indicated above, FIG. 4 is provided as an example. Other examples may differ from what is described with regard to FIG. 4.

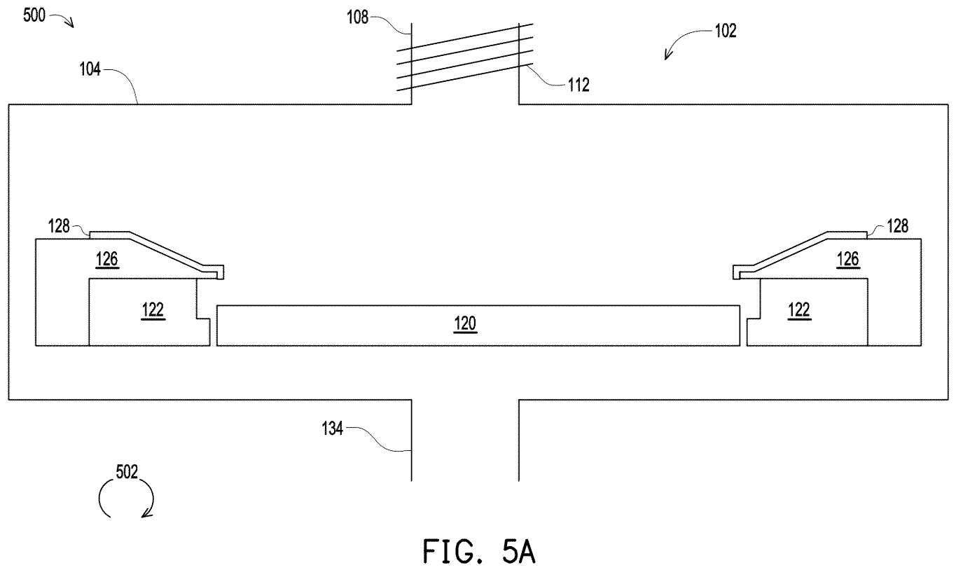

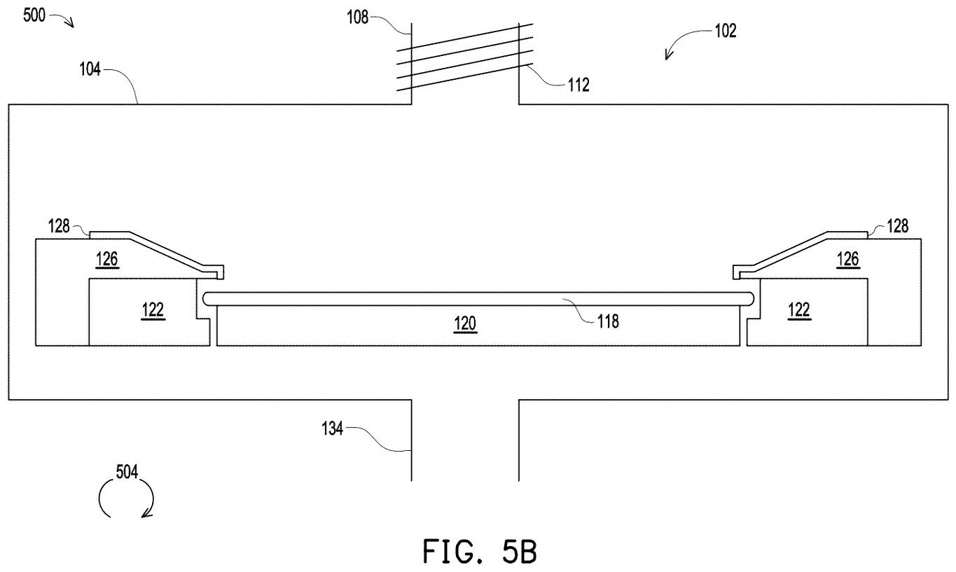

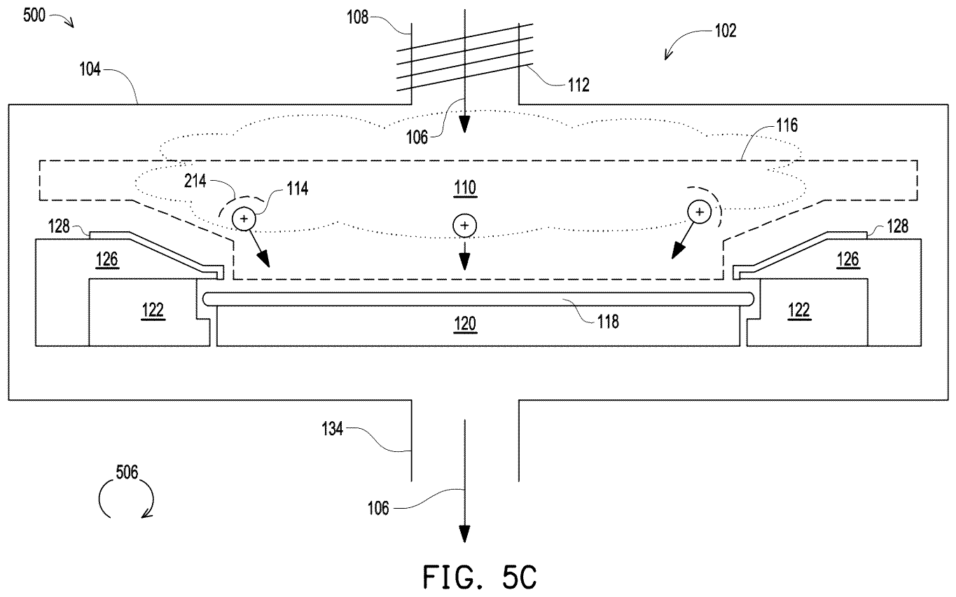

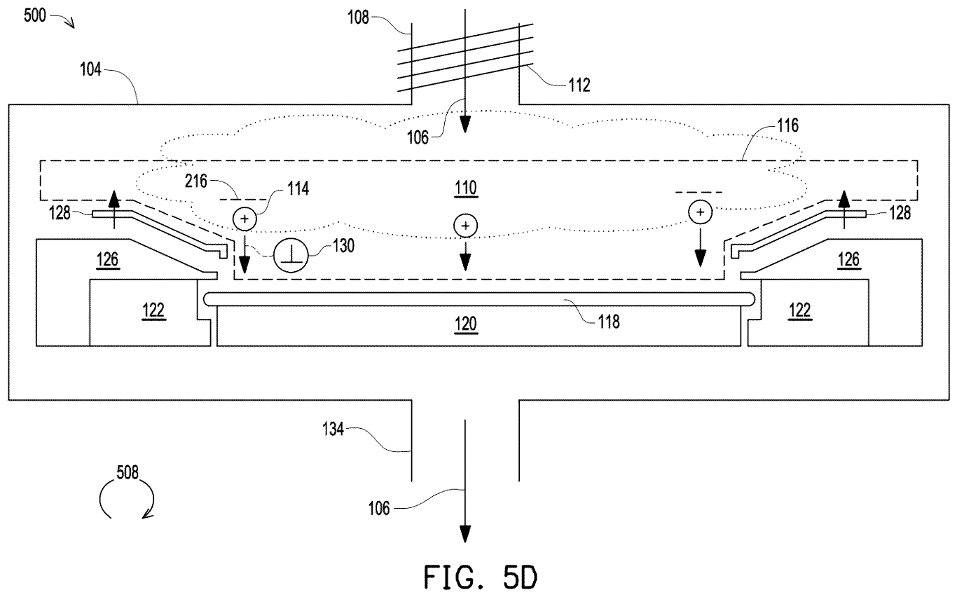

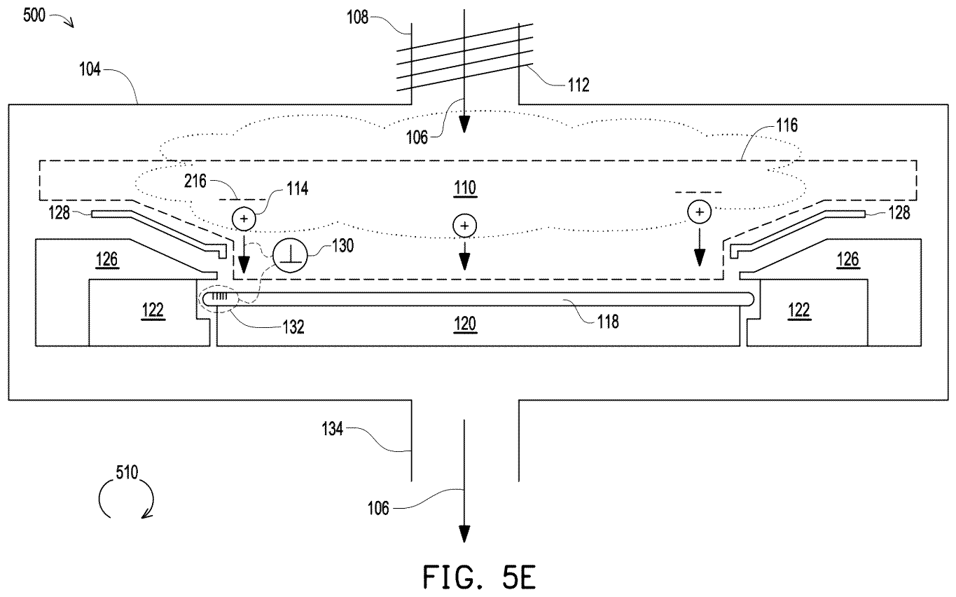

FIGS. 5A-5E are diagrams of an example series of operations 500 performed by the plasma etch system 102 described herein. In some implementations, one or more of the series of operations 500 is performed in the plasma etch system 102 in accordance with one or more determinations and/or command signals performed by a control system (e.g., the control system 136, among other examples).

The operation 502 in the side view of FIG. 5A shows a beginning state in which the chamber 104 is vacated (e.g., the chamber 104 does not include the plasma 110, the plasma sheath 116, and/or the semiconductor substrate 118). In some implementations, the operation 502 corresponds to an initiation operation. Further, and as shown in FIG. 5A, the moveable inner ring component 128 may be in a lowered position.

The operation 504 in the side view of FIG. 5B shows the plasma etch system 102 receiving the semiconductor substrate 118. For example, and as part of the operation 504, the semiconductor substrate 118 may be received onto the electrostatic chuck 120.

Turing to FIG. 5C, the side view of the operation 506 shows the plasma etch system 102 generating the plasma 110, including the plasma sheath 116, above the semiconductor substrate 118. For example, the operation 506 may include the initiation of a flow of the gas 106 through the inlet 108 (e.g., the controller 138 may activate the gas supply system 142) and the excitation of the gas 106 into the plasma 110 (e.g., the controller 138 may activate the power supply 144 to excite the gas 106 into the plasma 110).

In FIG. 5C, an electromagnetic profile of the plasma sheath 116 includes the concavity 214. In some implementations, the concavity 214 causes the ions 114 (e.g., the ions 114 near the edge of the semiconductor substrate 118) to be deflected at an angle.

In FIG. 5D, the side view of the operation 508 shows the plasma etch system 102 adjusting a height of a bottom surface of the moveable inner ring component 128 (e.g., the controller 138 may provide a signal to the mechanical lift component 140 to adjust the height of the bottom surface of the moveable inner ring component 128). Adjusting the height of the bottom surface of the moveable inner ring component may be based on an etch recipe and/or a targeted etch profile. Additionally, or alternatively, adjusting the height of the bottom surface of moveable inner ring component 128 may include using a machine learning model to determine one or more parameters related to adjusting the height.

In FIG. 5D, the electromagnetic profile of the plasma sheath 116 is adjusted to include the uniformity 216. In some implementations, the uniformity 216 improves the verticality 130 of ions 114 (e.g., the ions 114 near the edge of the semiconductor substrate 118).

FIG. 5E shows a side view of the operation 510. As part of the operation 510, the plasma etch system 102 removes material from the semiconductor substrate 118 using the plasma 110 to vertically etch an edge region of the semiconductor substrate 118. In FIG. 5E, removing the material is subsequent to adjusting the electromagnetic profile of the plasma sheath 116 (e.g., adjusting the electromagnetic profile 210a-210d to replace the concavity 214 with the uniformity 216) by adjusting the height of the moveable inner ring component 128.

As indicated above, FIGS. 5A-5E is provided as an example. Other examples, including a sequence or arrangement of the series of operations, and/or individual operations included in the series of operations, may differ from what is described with regard to FIGS. 5A-5E.

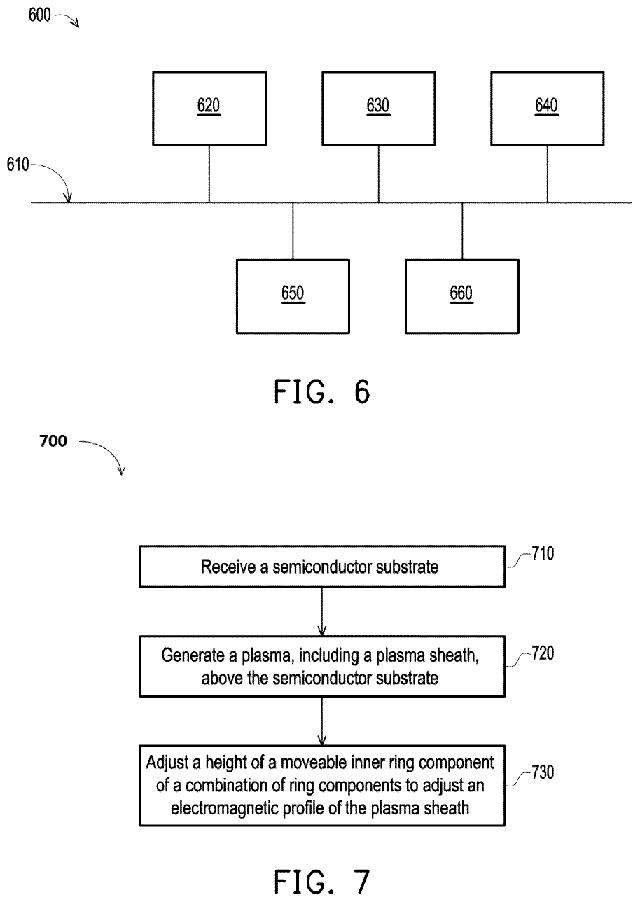

FIG. 6 is a diagram of example components of a device 600 associated with a tunable plasma sheath system for edge etch profile control. The device 600 may correspond to one or more components of the plasma etch system 102 including the controller 138, the mechanical lift component, 140, the gas supply system 142, and/or the power supply 144. In some implementations, the plasma etch system 102 including the controller 138, the mechanical lift component 140, the gas supply system 142, and/or the power supply 144 may include one or more devices 600 and/or one or more components of the device 600. As shown in FIG. 6, the device 600 may include a bus 610, a processor 620, a memory 630, an input component 640, an output component 650, and/or a communication component 660.

The bus 610 may include one or more components that enable wired and/or wireless communication among the components of the device 600. The bus 610 may couple together two or more components of FIG. 6, such as via operative coupling, communicative coupling, electronic coupling, and/or electric coupling. For example, the bus 610 may include an electrical connection (e.g., a wire, a trace, and/or a lead) and/or a wireless bus. The processor 620 may include a central processing unit, a graphics processing unit, a microprocessor, a controller, a microcontroller, a digital signal processor, a field-programmable gate array, an application-specific integrated circuit, and/or another type of processing component. The processor 620 may be implemented in hardware, firmware, or a combination of hardware and software. In some implementations, the processor 620 may include one or more processors capable of being programmed to perform one or more operations or processes described elsewhere herein.

The memory 630 may include volatile and/or nonvolatile memory. For example, the memory 630 may include random access memory (RAM), read only memory (ROM), a hard disk drive, and/or another type of memory (e.g., a flash memory, a magnetic memory, and/or an optical memory). The memory 630 may include internal memory (e.g., RAM, ROM, or a hard disk drive) and/or removable memory (e.g., removable via a universal serial bus connection). The memory 630 may be a non-transitory computer-readable medium. The memory 630 may store information, one or more instructions, and/or software (e.g., one or more software applications) related to the operation of the device 600. In some implementations, the memory 630 may include one or more memories that are coupled (e.g., communicatively coupled) to one or more processors (e.g., processor 620), such as via the bus 610. Communicative coupling between a processor 620 and a memory 630 may enable the processor 620 to read and/or process information stored in the memory 630 and/or to store information in the memory 630.

The input component 640 may enable the device 600 to receive input, such as user input and/or sensed input. For example, the input component 640 may include a touch screen, a keyboard, a keypad, a mouse, a button, a microphone, a switch, a sensor, a global positioning system sensor, an accelerometer, a gyroscope, and/or an actuator. The output component 650 may enable the device 600 to provide output, such as via a display, a speaker, and/or a light-emitting diode. The communication component 660 may enable the device 600 to communicate with other devices via a wired connection and/or a wireless connection. For example, the communication component 660 may include a receiver, a transmitter, a transceiver, a modem, a network interface card, and/or an antenna.

The device 600 may perform one or more operations or processes described herein. For example, a non-transitory computer-readable medium (e.g., memory 630) may store a set of instructions (e.g., one or more instructions or code) for execution by the processor 620. The processor 620 may execute the set of instructions to perform one or more operations or processes described herein. In some implementations, execution of the set of instructions, by one or more processors 620, causes the one or more processors 620 and/or the device 600 to perform one or more operations or processes described herein. In some implementations, hardwired circuitry may be used instead of or in combination with the instructions to perform one or more operations or processes described herein. Additionally, or alternatively, the processor 620 may be configured to perform one or more operations or processes described herein. Thus, implementations described herein are not limited to any specific combination of hardware circuitry and software.

The number and arrangement of components shown in FIG. 6 are provided as an example. The device 600 may include additional components, fewer components, different components, or differently arranged components than those shown in FIG. 6. Additionally, or alternatively, a set of components (e.g., one or more components) of the device 600 may perform one or more functions described as being performed by another set of components of the device 600.

FIG. 7 is a flowchart of an example process 700 associated with tunable plasma sheath system for edge etch profile control. In some implementations, one or more process blocks of FIG. 7 are performed the tunable. In some implementations, one or more process blocks of FIG. 7 are performed by another device or a group of devices separate from or including the plasma etch system 102, such as the controller 138, the mechanical lift component, 140, the gas supply system 142, and/or the power supply 144. Additionally, or alternatively, one or more process blocks of FIG. 7 may be performed by one or more components of device 600, such as processor 620, memory 630, input component 640, output component 650, and/or communication component 660.

As shown in FIG. 7, process 700 may include receiving a semiconductor substrate (block 710). For example, the electrostatic chuck 120 of the plasma etch system 102 may receive a semiconductor substrate 118, as described above.

As further shown in FIG. 7, process 700 may include generating a plasma, including a plasma sheath, above the semiconductor substrate (block 720). For example, the plasma etch system 102 may generate a plasma 110, including a plasma sheath 116 above the semiconductor substrate 118, as described above.

As further shown in FIG. 7, process 700 may include adjusting a height of a moveable inner ring component of a plasma sheath tuning system to adjust an electromagnetic profile of the plasma sheath (block 730). For example, the mechanical lift component 140 of the plasma etch system 102 may adjust a height of a moveable inner ring component 128 of a plasma sheath tuning system to adjust an electromagnetic profile 210a-210d of the plasma sheath 116, as described above. In some implementations, the plasma sheath tuning system includes an edge ring component 122, a fixed outer ring component 126, and the moveable inner ring component 128. In some implementations, the moveable inner ring component 128 is above the edge ring component 122 component and the fixed outer ring component 126.

Process 700 may include additional implementations, such as any single implementation or any combination of implementations described below and/or in connection with one or more other processes described elsewhere herein.

In a first implementation, adjusting the height of a bottom surface of the moveable inner ring component 128 includes adjusting the height a vertical distance (D11) that is included in a range of approximately 1 millimeter to approximately 23 millimeters.

In a second implementation, alone or in combination with the first implementation, adjusting the electromagnetic profile 210a-210d adjusts a concavity of 214 the plasma sheath 116 to increase a verticality 130 of a bombardment of ions 114 above a perimeter region of the semiconductor substrate 118.

In a third implementation, alone or in combination with one or more of the first and second implementations, adjusting the height of the moveable inner ring component 128 includes using a pin component 412 below the moveable inner ring component 128.

In a fourth implementation, alone or in combination with one or more of the first through third implementations, adjusting the height of the moveable inner ring component 128 includes using an elevator component 408 side-by-side with the moveable inner ring component 128.

In a fifth implementation, alone or in combination with one or more of the first through fourth implementations, adjusting the height of the moveable inner ring component 128 includes using an upper cantilever component 410 above the moveable inner ring component 128.

In a sixth implementation, alone or in combination with one or more of the first through fifth implementations, adjusting the height of the moveable inner ring component 128 includes determining, by a controller 138 using a machine learning model, an adjustment to a setting controlling the height of the moveable inner ring component 128.

In a seventh implementation, alone or in combination with one or more of the first through sixth implementations, process 700 includes removing material from the semiconductor substrate 118 using the plasma 110 to vertically etch an edge region of the semiconductor substrate 118. In some implementations, removing the material is subsequent to adjusting the electromagnetic profile 210a-210d of the plasma sheath 116 by adjusting the height of the moveable inner ring component 128.

Although FIG. 7 shows example blocks of process 700, in some implementations, process 700 includes additional blocks, fewer blocks, different blocks, or differently arranged blocks than those depicted in FIG. 7. Additionally, or alternatively, two or more of the blocks of process 700 may be performed in parallel.

Some implementations described herein include an etch tool including a combination bottom shadow ring component including a moveable inner ring component and a fixed inner ring component. The moveable inner ring component provides for an adjustability of an effective thickness of the combination bottom shadow ring component during an etching operation. The adjustability (e.g., “tunability”) of the effective thickness of the combination bottom shadow ring component enables flexibility and is conducive to changes in one or more parameters related to different etch recipes for a semiconductor substrate. Additionally, the fixed inner ring component shadows beveled regions of the semiconductor substrate during the etching operation to reduce a likelihood of damage to the beveled regions.

In this way, a productivity of the etch tool including the combination bottom shadow ring component may be increased relative to another etch tool not including the combination bottom shadow ring component (e.g., a downtime of the etch tool for changing between bottom shadow rings of different thicknesses may be eliminated). Additionally, a yield of a semiconductor product fabricated using the etch tool may increase (relative to the other tool) to reduce an amount of resources required to fabricate a volume of the semiconductor product (e.g., an install base of the etch tool, an amount of semiconductor substrates, and or supporting computing resources, among other examples).

As described in greater detail above, some implementations described herein provide a plasma sheath tuning system for a plasma etch tool. The plasma sheath tuning system for plasma etch tool includes an edge ring component. The plasma heath tuning system for plasma etch tool includes a combination bottom shadow ring component. The combination bottom shadow ring component includes a fixed outer ring component and a moveable inner ring component. The moveable inner ring component is above the fixed outer ring component.

As described in greater detail above, some implementations described herein provide a plasma etch tool. The plasma etch tool includes a chamber. The plasma etch tool includes an electrostatic chuck in the chamber to support a semiconductor substrate. The plasma etch tool includes a subsystem configured to adjust an electromagnetic profile of a plasma sheath within the chamber above a perimeter region of the semiconductor substrate. The subsystem includes a combination bottom shadow ring component that includes a fixed outer ring component and a moveable inner ring component above the fixed outer ring component. The subsystem includes a mechanical lift component connected to the moveable inner ring component. In some implementations, the mechanical lift component is configured to adjust a height of a bottom surface of the moveable inner ring component to adjust the electromagnetic profile of the plasma sheath.

As described in greater detail above, some implementations described herein provide a method. The method includes receiving a semiconductor substrate. The method includes generating a plasma that includes a plasma sheath above the semiconductor substrate. The method includes adjusting a height of a moveable inner ring component of a plasma sheath tuning system to adjust an electromagnetic profile of the plasma sheath. In some implementations, the plasma sheath tuning system includes an edge ring component, a fixed outer ring component, and the moveable inner ring component, where the moveable inner ring component is above the edge ring component and the fixed outer ring component.

As used herein, the term “and/or,” when used in connection with a plurality of items, is intended to cover each of the plurality of items alone and any and all combinations of the plurality of items. For example, “A and/or B” covers “A and B,” “A and not B,” and “B and not A.”

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
receiving a semiconductor substrate;
generating a plasma, including a plasma sheath, above the semiconductor substrate; and
adjusting a height of a top surface of a moveable inner ring component of multiple ring components to adjust an electromagnetic profile of the plasma sheath,
wherein the multiple ring components comprise an edge ring component, a fixed outer ring component, and the moveable inner ring component, and
wherein the moveable inner ring component is above the edge ring component and the fixed outer ring component.

2. The method of claim 1, wherein adjusting the height of the top surface of the moveable inner ring component comprises:
adjusting the height a vertical distance in a range of approximately 1 millimeter to approximately 23 millimeters.

3. The method of claim 1, wherein adjusting the electromagnetic profile comprises:
adjusting a concavity of the plasma sheath to increase a verticality of a bombardment of ions above a perimeter region of the semiconductor substrate.

4. The method of claim 1, wherein adjusting the height of the top surface of the moveable inner ring component comprises:
using a pin component below the moveable inner ring component to adjust the height.

5. The method of claim 1, wherein adjusting the height of the top surface of the moveable inner ring component comprises:
using an elevator component that is side-by-side with the moveable inner ring component to adjust the height.

6. The method of claim 1, wherein adjusting the height of the top surface of the moveable inner ring component comprises:
using an upper cantilever component above the moveable inner ring component to adjust the height.

7. The method of claim 1 further comprising:
determining, using a machine learning model, an adjustment to a setting controlling the height.

8. The method of claim 1, further comprising:
removing, after adjusting the height of the moveable inner ring component, material from the semiconductor substrate using the plasma to vertically etch an edge region of the semiconductor substrate.

9. A method, comprising:
receiving a semiconductor substrate within a chamber;
forming a plasma sheath above the semiconductor substrate;
determining, using a machine learning model, a height adjustment of a moveable inner ring component positioned above a fixed outer ring component and an edge ring component surrounding the semiconductor substrate; and
adjusting a height of the moveable inner ring component based on the height adjustment.

10. The method of claim 9, further comprising:
removing, after adjusting the height of the moveable inner ring component, material from the semiconductor substrate using the plasma sheath.

11. The method of claim 9, wherein the height adjustment is determined based on a received etch profile for a perimeter of the semiconductor substrate.

12. The method of claim 9, wherein adjusting the height of the moveable inner ring component comprises:
actuating a mechanical lift component connected to the moveable inner ring component.

13. The method of claim 9, wherein the height adjustment is between a bottom surface of the moveable inner ring component and a top surface of surface of the moveable inner ring component and is in a range of approximately 1 millimeter to approximately 23 millimeters.

14. The method of claim 9, wherein adjusting the height of the moveable inner ring component is associated with an even distribution of electrical potential bands of an electromagnetic field.

15. The method of claim 9, wherein adjusting the height of the moveable inner ring component corresponds to a change, in a tilt angle of ion bombardment, in a range of approximately +7 degrees to −13 degrees.

16. A method, comprising:
receiving a semiconductor substrate onto an electrostatic chuck;
generating a plasma sheath above the semiconductor substrate;
raising, by a mechanical lift component, a moveable inner ring component above a fixed outer ring component to an elevated position; and
vertically, after raising the moveable inner ring component, etching an edge region of the semiconductor substrate using the plasma sheath.

17. The method of claim 16, wherein raising the moveable inner ring component comprises:
aligning a complementary angled surface of the moveable inner ring component with an angled surface of the fixed outer ring component.

18. The method of claim 16, wherein, after vertically etching the edge region, an electromagnetic profile of the plasma sheath includes a region having electrical potential bands that are evenly distributed and approximately linear.

19. The method of claim 16, wherein the moveable inner ring component includes a lip portion that overlaps a shadow portion of the fixed outer ring component.

20. The method of claim 16, wherein the fixed outer ring component includes a shadow portion extending over a perimeter of the semiconductor substrate.
